(19) United States
(12) Patent Application Publication
(10) Pub. No.: US 2013/0285097 A1
(43) Pub. Date: Oct. 31, 2013

(54) SIDE-VIEW LIGHT EMITTING DIODE PACKAGE AND METHOD FOR MANUFACTURING THE SAME

(71) Applicant: ADVANCED OPTOELECTRONIC TECHNOLOGY, INC., Hsinchu Hsien (TW)

(72) Inventors: LUNG-HSIN CHEN, Hsinchu (TW); HSING-FEN LO, Hsinchu (TW); WEN-LIANG TSENG, Hsinchu (TW)

(73) Assignee: ADVANCED OPTOELECTRONIC TECHNOLOGY, INC., Hsinchu Hsien (TW)

(21) Appl. No.: 13/868,111

(22) Filed: Apr. 23, 2013

(30) Foreign Application Priority Data
Apr. 27, 2012 (CN) 2012101278227

(51) Int. Cl. H01L 33/60

(52) U.S. Cl. CPC H01L 33/60
USPC 257/98; 438/27

(57) ABSTRACT

A side-view LED package includes a substrate, a pair of electrodes connected to the substrate, an LED die electrically connected to the electrodes, a reflective cup formed on the substrate, an opening defined at a lateral side of the reflective cup, an encapsulation formed on the substrate to cover the LED die, and a reflective layer coated on a top of the encapsulation and a top of the reflective cup, wherein part of light emitting from the LED die is reflected by the reflective cup and the reflective layer and then emits out of the side-view LED package from the opening. The present disclosure also provides a method for manufacturing the side-view LED package described above.

### BACKGROUND

1. Technical Field

The present disclosure generally relates to a light emitting diode (LED) package and method for manufacturing the same, and particularly to an LED package which emits light laterally and a method for manufacturing the same.

2. Description of Related Art

In recent years, due to excellent light quality and high luminous efficiency, light emitting diodes (LEDs) have increasingly been used as substitutes for incandescent bulbs, compact fluorescent lamps and fluorescent tubes as light sources of illumination devices.

Nowadays a lighting device often requires a light source which can emit light laterally. Accordingly, in many instances, for emitting light laterally, an LED chip is arranged on a side of an LED package. However, compared with the typical top-view LED package, a position of the LED chip needs to be changed, which results in a redesigning of a circuit connection and a space arrangement inside the LED package. Alternatively, a special reflective portion is added in the LED package to obtain lateral light. However, such an addition of the special reflective portion complicates the design and manufacture of the LED package. Both the conventional ways to obtain a side-view LED package need to adjust the inner structure of the lighting device, which makes the structure complicated and is difficult for mass production.

Therefore, what is needed is to provide a side-view LED package and method of manufacturing the same which can overcome the above shortcomings.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the disclosure.

FIG. 1 is a schematic, cross-sectional view of a side-view LED package in accordance with an exemplary embodiment of the present disclosure.

FIGS. 2-8 are schematic cross sections showing different steps for manufacturing the side-view LED package of FIG. 1.

### DETAILED DESCRIPTION

Reference will now be made to the drawings to describe the present side-view LED package, and a method for making the side-view LED package, in detail.

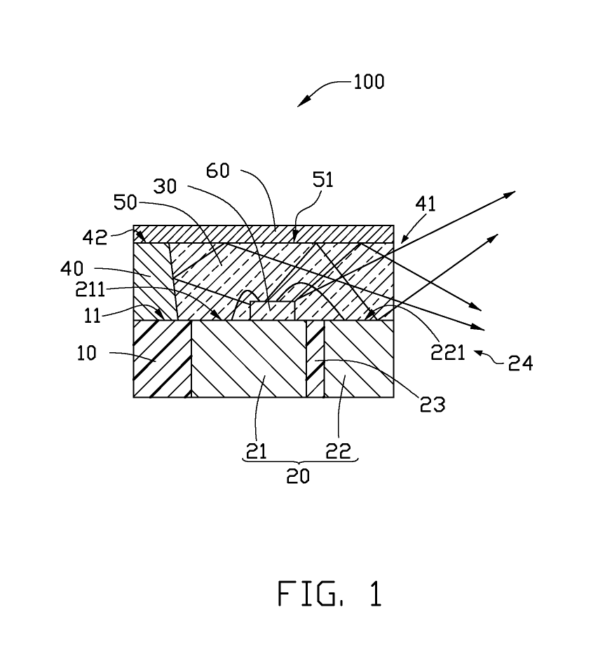

Referring to FIG. 1, a side-view LED package 100 of the present disclosure is provided. The side-view LED package 100 includes a substrate 10, two electrodes 20, an LED die 30, a reflective cup 40, an encapsulation 50, and a reflective layer 60. The two electrodes 20 are formed on the substrate 10 and spaced from each other. The LED die 30 is mounted on one of the electrodes 20 and electrically connected to the electrodes 20 via metallic wires (not labeled). The reflective cup 40 is positioned on lateral sides of the LED die 30. The lateral sides, as viewed from FIG. 1, include a left side, a front side and a rear side of the side-view LED package 100. Only the right side of the LED die 30 is not blocked by the reflective cup 40 whereby the light generated by the LED chip 30 can leave the side-view LED package 100 via the right side thereof. The encapsulation 50 covers the LED die 30 on the substrate 10.

The substrate 10 is generally a plate in shape. The substrate includes four sides, i.e., a first (front) side, a second (left) side, a third (rear) side, and a fourth (right) side.

The reflective cup 40 is formed along three adjacent sides, including the first side, the second side and the third side on the substrate 10, with an opening 41 defined above the fourth side of the substrate 10. Light emitted from the LED die 30 can emit out of the side-view LED package 100 from the opening 41. In other words, the opening 41 is defined in the integrally formed reflective cup 40 which partially surrounds the LED die 30, thereby allowing light to emit out from the opening 41. Alternatively, the substrate 10 can be round or elliptical in shape. The opening 41 is accordingly formed in the reflective cup 40 at a lateral side of the LED die 30.

The encapsulation 50 is filled in the reflective cup 40 and is coplanar with the fourth side of the substrate 10 at the opening 41. A top surface 51 of the encapsulation 50 is coplanar with a top surface 42 of the reflective cup 40. The reflective layer 60 is coated on the top surface 51 of the encapsulation 50 and the top face 42 of the reflective cup 40, and faces a light emitting top surface of the LED die 30.

A part of the light emitting from the LED die 30 strikes on the reflective cup 40 and then is reflected by the reflective cup 40 to the reflective layer 60, and emits out from the opening 41 by reflection of the reflective layer 60. Another part of the light emitting from the LED die 30 strikes on the reflective layer 60 or the reflective cup 40, and then is reflected directly by the reflective layer 60 or the reflective cup 40 to emit out of the side-view LED package 100 from the opening 41. The rest of the light emits out from the opening 41 directly.

The electrodes 20 include a first electrode 21 and a second electrode 22. An insulative layer 23 which is a part the substrate 10 is formed between the first and second electrode 21, 22 to electrically insulate the first electrode 21 from the second electrode 22.

The first electrode 21 has an upper surface 211 exposed out of an upper surface 11 of the substrate 10. The second electrode 22 has an upper surface 221 exposed out of the upper surface 11 of the substrate 10. An area of the upper surface 211, 221 of each of the first electrode 21 and the second electrode 22 is larger than that of the insulative layer 23. The exposed upper surfaces 211, 221 of the first electrode 21 and the second electrode 22 are used as a reflective surface 24, because the electrodes 20 are made of metal which can effectively reflect light. As such, light emitting from the LED die 30 will be reflected by the reflective surface 24 and emit out from the opening 41 of the reflective cup 40 when strikes on the upper surface of the electrodes 20.

In the present side-view LED package 100, the another part of the light emitted from the LED die 30 strikes on the reflective layer 60 facing the LED die 30, the part of the light strikes on the reflective cup 40 at lateral sides of the LED die 30, and the rest of the light emits out from the opening 41 directly. The light striking on the reflective layer 60 is reflected by the reflective layer 60, then part of the light strikes on the upper surface of the electrodes 20, and the rest of the light travels out of the opening 41. The light striking on the reflective cup 40 is reflected by the reflective cup 40, then part of the light is reflected by the reflective layer 60 to strike on the upper surface of the electrodes 20, and the rest of the light is reflected by the reflective layer 60 to travel out of the opening 41. The light striking on the electrodes 20 is reflected by the reflective surface 24, and finally travels out of the side-view LED package 100 via the opening 41. The light emitting from the LED die 30 can be reflected by the reflective cup 40, the reflective layer 60, and the reflective surface 24 and then travel out from the opening 41 which is at the lateral side of the LED die 30. Thus, the light can emit out of the side-view LED package 100 laterally. A configuration of the present side-view LED package 100 is simple, and an arrangement of the electrodes 20 is the same as that of a conventional top-view LED package. So the position of the LED die 30 does not need to be changed and a redesigning of a circuit connection is not required.

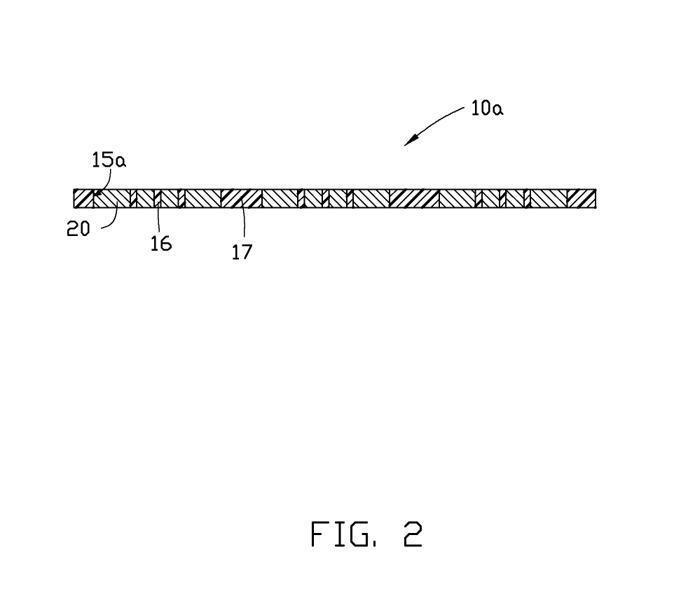

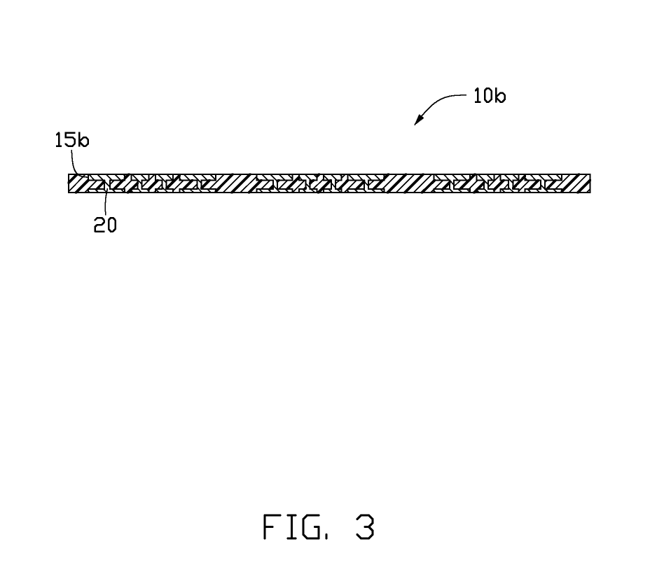

Referring to FIGS. 2-8, a method for manufacturing the side-view LED package 100 in accordance with the present disclosure includes steps of:
Step 1: providing a supporting board 10a and forming a plurality of electrodes 20 in the supporting board 10a as shown in FIG. 2, or providing a supporting board 10b forming a plurality of the electrodes 20 in the supporting board 10b as shown in FIG. 3, wherein the following steps are applied to the supporting board 10a, and however they can also be applied to the supporting board 10b;
Step 2: forming a plurality of reflective cups 40a on the supporting board 10a;
Step 3: mounting a plurality of LED dies 30 on the supporting board 10a and electrically connecting every two adjacent LED dies 30 to two pairs of electrodes 20 in each reflective cup 40a, wherein each reflective cup 40a totally surrounds the two adjacent LED dies 30;
Step 4: electrically connecting the LED die 30 to the electrodes 20 and forming an encapsulation 50 in each reflective cup 40a to cover and encapsulate the LED dies 30 on the supporting board 10a;
Step 5: coating a reflective layer 60 on a top surface of the encapsulation 50 and a top surface of the reflective cups 40a;
Step 6: cutting the supporting board 10a and each reflective cup 40a to separate each reflective cup 40a into two parts, wherein each of the two parts of the cut reflective cup 40a has an opening 41 facing that of the other one of the two parts of the cut reflective cup 40a.

In step 1, referring to FIG. 2, the supporting board 10a is provided with a plurality of through holes 15a. The supporting board 10a is substantially a plate in shape and can be made of high polymer materials or plastic such as epoxy or silicone. The through holes 15a include at least one group of through holes 15a, and each group includes at least four through holes 15a. In this embodiment, a diameter of each through hole 15a is larger than a distance between every two adjacent through holes 15a in each group. In this embodiment, the groups of the through holes 15a are three. A part of the supporting board 10a between every two adjacent through holes 15a forms a first insulating portion 16. A distance between every two adjacent groups of the through holes 15a is larger that the diameter of each through hole 15a. A second insulating portion 17 is formed between every two adjacent groups of the through holes 15a. A width of the first insulating portion 16 is smaller than that of the second insulating portion 17. Four electrodes 20 are formed by filling each group of the through holes 15a with metal.

Alternatively, the through holes 15a can be different shapes, for example, as shown in FIG. 3. Each through hole 15b is I-shaped. As such, the electrodes 20 formed in the through holes are I-shaped, with larger surface exposed out of a top surface and a bottom surface of the supporting board 10b. The supporting board 10b in this embodiment is made of composite material such as fiber-reinforced plastic. The supporting board 10b and the electrodes 20 in this embodiment can be formed as a printed circuit board (PCB) or a metal cored printed circuit board (MCPCB).

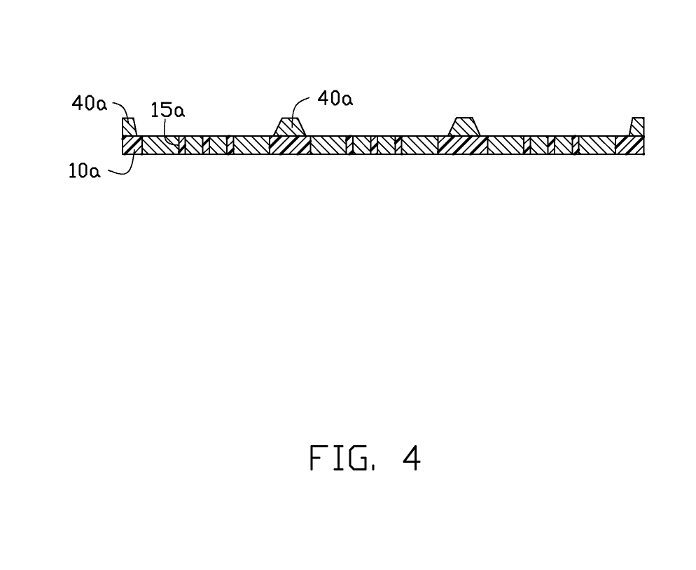

In step 2, referring to FIG. 4, the reflective cups 40a are formed on the second insulating portion 17 of the supporting board 10a. Each reflective cup 40a surrounds one group of the through holes 15a. Each reflective cup 40a has a reflective surface inclined from the top surface of the supporting board 10a upwardly and outwardly.

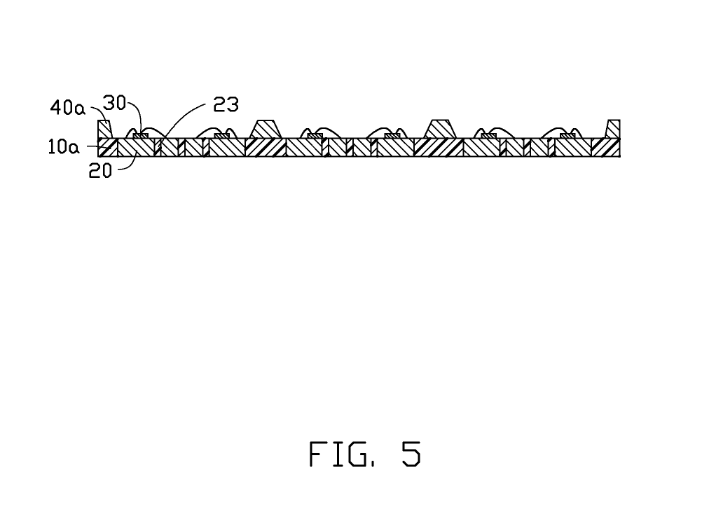

In step 3, referring to FIG. 5, there are at least two LED dies 30 received in each reflective cup 40a and mounted on the supporting board 10a. Each LED die 30 is connected to the electrodes 20 by wire bonding. The LED die 30 can also be connected to the electrodes 20 by flip chip bonding or eutectic bonding. Every two adjacent electrodes 20 are spaced from each other with the insulating portion 16 which acts as an insulative layer 23 filled therebetween.

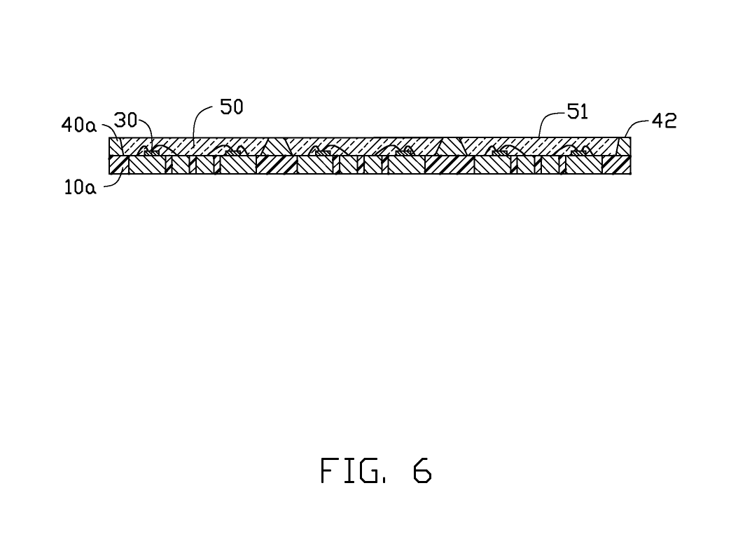

In step 4, referring to FIG. 6, the encapsulation 50 can be formed by injection molding or compression molding. A top surface 51 of each encapsulation 50 is coplanar with a top surface 42 of each reflective cup 40a.

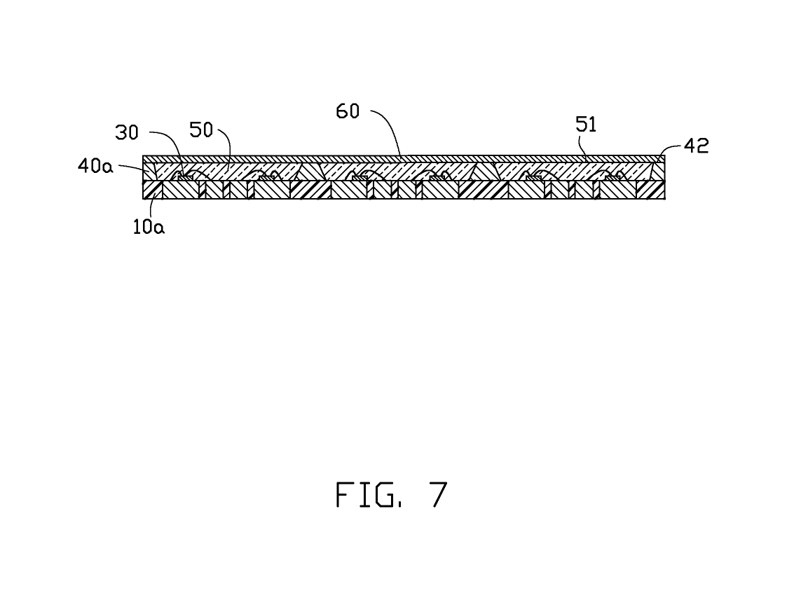

In step 5, referring to FIG. 7, the reflective layer 60 is made of metal film, such as aluminum, silver or an alloy thereof. The reflective layer 60 is coated on the top surface 51 of the encapsulation 50 and further extends to cover the top surface 42 of the reflective cups 40a. The reflective layer 60 covers gaps between the reflective cups 40a and the encapsulation 50, thereby preventing moisture and dust from infiltrating into the side-view LED package 100. The reflective layer 60 can be made by PVD (Physical Vapor Deposition), compression molding, or spraying. A thickness of the reflective layer 60 is between 0.03 μm and 2 μm.

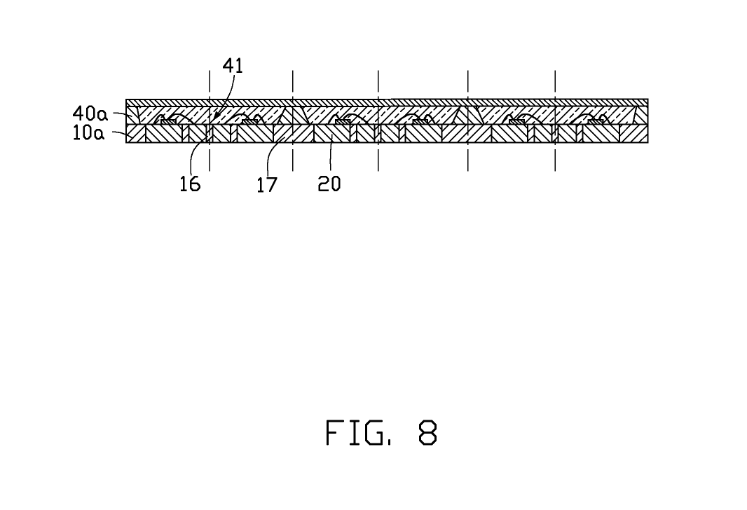

In step 6, referring to FIG. 8, there are two cutting processes in this step. A first cutting is operated on the second insulating portion 17 and the reflective cups 40a formed thereon, thereby separating the assembly of FIG. 7 into a plurality of units each including a reflective cup 40a surrounding two LED chips 30. A second cutting is operated on a center of each individual reflective cup 40a, thereby obtaining two reflective cups 40 each forming a corresponding opening 41. Accordingly, the side-view LED package 100 of FIG. 1 is obtained. Each reflective cup 40a is cut medially at the first insulating portion 16 of FIG. 8, thereby obtaining two LED packages 100, as shown in FIG. 1.

It is to be understood that the above-described embodiments are intended to illustrate rather than limit the disclosure. Variations may be made to the embodiments without departing from the spirit of the disclosure as claimed. The above-described embodiments illustrate the scope of the disclosure but do not restrict the scope of the disclosure.

What is claimed is:

1. A side-view LED (light emitting diode) package, comprising:
a substrate;
a pair of electrodes connected to the substrate;
an LED die electrically connected to the pair of electrodes;
a reflective cup formed on the substrate, an opening defined at a lateral side of the reflective cup;
an encapsulation formed on the substrate to cover the LED die; and
a reflective layer coated on the encapsulation;
wherein part of light emitting from the LED die is reflected by the reflective cup and the reflective layer and then emits out of the side-view LED package from the opening.

2. The side-view LED package of claim 1, wherein the substrate comprises four sides, the reflective cup is formed along three sides of the substrate, and the opening is defined above a remaining side of the substrate.

3. The side-view LED package of claim 2, wherein a lateral side of the encapsulation is coplanar with the remaining side of the substrate.

4. The side-view LED package of claim 1, wherein a top surface of the encapsulation is coplanar with a top surface of the reflective cup.

5. The side-view LED package of claim 4, wherein the reflective layer covers both the top surfaces of the encapsulation and the reflective cup.

6. The side-view LED package of claim 1, wherein the pair of the electrodes comprises a first electrode and a second electrode, and an insulative layer is located between the first electrode and the second electrode to electrically insulate the first electrode from the second electrode.

7. The side-view LED package of claim 6, wherein each of the first electrode and the second electrode has an upper surface exposed out of an upper surface of the substrate, an area of the upper surface of each of the first electrode and the second electrode is larger than that of the insulative layer.

8. A method for manufacturing a side-view LED package, comprising steps:
Step 1: providing a supporting board with a plurality of pairs of electrodes;
Step 2: forming a plurality of reflective cups on the supporting board, each reflective cup totally surrounding two pairs of electrodes;
Step 3: mounting a plurality of LED dies on the supporting board wherein each reflective cup totally surrounds adjacent two of the LED dies and electrically connecting each of the adjacent two of the LED dies to a corresponding one pair of the electrodes in each reflective cup;
Step 4: forming an encapsulation in each reflective cup and covering the LED dies on the supporting board by the encapsulation;
Step 5: coating a reflective layer on a top surface of the encapsulation;
Step 6: cutting the supporting board and each reflective cup to separate each reflective cup into two parts, each part of the cut reflective cup surrounding three sides of a corresponding LED die and defining an opening at a lateral side thereof to obtain the side-view LED package such that light emitted from the corresponding LED die emits out of the side-view LED package through the opening.

9. The method for manufacturing a side-view LED package of claim 8, wherein the supporting board comprises a plurality of groups of through holes in which the electrodes are received, and each group of the through holes comprises four through holes.

10. The method for manufacturing a side-view LED package of claim 9, wherein each of the through holes is I-shaped.

11. The method for manufacturing a side-view LED package of claim 9, wherein a first insulating portion is formed between every two adjacent through holes in each group of the through holes, a second insulating portion is formed between every two groups of the through holes, and a width of the first insulating portion is smaller than that of the second insulating portion.

12. The method for manufacturing a side-view LED package of claim 11, wherein the reflective cups are formed on the second insulating portions of the supporting board, and each reflective cup surrounds one group of the through holes.

13. The method for manufacturing a side-view LED package of claim 12, wherein the step of cutting the supporting board and each reflective cup to separate each reflective cup into two parts comprises two cutting processes:
cutting the second insulating portions of the supporting board and the reflective cups formed on the second insulating portions into a plurality of units each comprising a corresponding reflective cup surrounding two corresponding LED dies; and
cutting the corresponding reflective cup to the two parts each surrounding three sides of one of the two corresponding LED dies.

14. The method for manufacturing a side-view LED package of claim 8, wherein the reflective layer is coated on a top surface of each encapsulation and a top surface of each reflective cup.
